(19) United States
(12) Patent Application Publication
(10) Pub. No.: US 2004/0124491 A1
(43) Pub. Date: Jul. 1, 2004

(54) Semiconductor device having high impurity concentration region and low impurity concentration region in side surface of active region

(75) Inventors: Tomohiro Yamashita, Tokyo (JP); Katsuyuki Horita, Tokyo (JP); Takashi Kuroi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/452,312

(22) Filed: Jun. 3, 2003

(30) Foreign Application Priority Data
Dec. 25, 2002 (JP) 2002-374195

(51) Int. Cl. H01L 29/00

(52) U.S. Cl. 257/506

(57) ABSTRACT

A high impurity concentration region (31) that an impurity concentration is higher than that of a center part of a channel region (24) is placed in parts which intersect a Y direction in a side surface (14T) of an active region (14). Furthermore, a low impurity concentration region (32) that an impurity concentration is lower than that of the high impurity concentration region (31) is placed in parts which intersect an X direction in the side surface (14T). A source/drain region (231) overlaps with the low impurity concentration region (32), and in that overlapped part, the formation of a high concentration PN junction is suppressed.

### BACKGROUND OF THE INVENTION

1. Field of the Invention

The present invention relates to a semiconductor device and a manufacturing method thereof, and more concretely, it relates to a technique which suppresses both what is called an inverse narrow channel effect and a junction leakage current generated between a source/drain region and a substrate simultaneously in MISFET (Metal-Insulator-Semiconductor Field Effect Transistor).

2. Description of the Background Art

For example, with regard to a DRAM (Dynamic Random Access Memory), a reduction of a memory cell size is planned in order to reduce a chip size and increase a memory bit in number. At this time, an element isolation width can be reduced by a trench type element isolation more than a LOCOS (LOCal Oxidation of Silicon).

However, in case of using the trench type element isolation, there is a possibility that what is called an inverse narrow channel effect is generated that a parasitic MOSFET (Metal-Oxide-Semiconductor Field Effect Transistor) at a rim part or an edge part of an active region decreases a threshold value of (an intrinsic) MOSFET and increases an off current of the MOSFET.

Therefore, in a conventional semiconductor device, an impurity concentration at an edge part of a channel region of the MOSFET is raised by raising an impurity concentration at an edge part in a main surface of the active region, and according to this, the inverse narrow channel effect is suppressed (refer to FIGS. 14 and 15 described hereinafter). Such a high impurity concentration region is formed in the following steps.

First, a silicon oxide film and a silicon nitride film are formed in order on a main surface of a semiconductor substrate, and they are patterned on a plane pattern of the active region. Then, a trench is formed by etching the semiconductor substrate, using the silicon oxide film and the silicon nitride film as a mask. Afterwards, by an oblique implantation method, an ion implantation of the impurities is performed toward a side surface of the active region exposed in the trench, and the impurity concentration at that side surface is increased, and according to this, the impurity concentration at the edge part described above is increased.

At this time, in the conventional semiconductor device, the ion implantation is performed from all directions to form the high impurity concentration region at the entire edge part of the main surface of the active region, that is to say, at the entire rim of it. Concretely, the ion implantation is performed by rotating continuously, or it is performed from four directions or more by rotating stepwise.

Moreover, in case that the plural active regions are placed such as a memory cell region of the DRAM, an implantation angle is selected so that the ion implantation is performed to each active region. For example, when a total thickness of the silicon oxide film and the silicon nitride film described above is described as t and the smallest distance between the active regions (in other words, the smallest isolation width) is described as dx and dy in an X direction and a Y direction (both of them are parallel with the main surface and moreover, run at right angles to each other), an implantation angle θ given as an inclined angle to a normal direction of the main surface is set to satisfy both θ<tan⁻¹(dx/t) and θ<tan⁻¹(dy/t).

Besides, after the ion implantation, the silicon oxide film is embedded in the trench, that silicon oxide film is flatted, the silicon nitride film and the silicon oxide film are removed and then, the trench type element isolation is completed.

Besides, a technique to perform the ion implantation at the side surface of the trench after forming that trench in the semiconductor substrate is introduced in a patent document 1 (Japanese Patent Application Laid-Open No. 2001-36079), for example.

As described above, in the conventional manufacturing method, the high impurity concentration region described above is formed on the entire rim part of the main surface of the active region, thus the high impurity concentration region is also formed in a region where a source/drain region of the MOSFET is supposed to be formed, and accordingly, in a complete semiconductor device, the high impurity concentration region and the source/drain region form a high concentration PN junction. Therefore, there is a problem that a junction leakage current is large in the conventional semiconductor device. Moreover, the junction leakage current causes an increase of a consumed power and a decrease of a yield, and also causes a deterioration of a refresh characteristic in the DRAM, for example.

### SUMMARY OF THE INVENTION

The present invention is provided in view of points described above, and it is an object of the present invention to provide a semiconductor device which can suppress an inverse narrow channel effect and a junction leakage current generated between a source/drain region and a substrate simultaneously.

According to the present invention, a semiconductor device includes an active region including a main surface and a side surface, a trench type element isolation, gate electrode, a channel regions, source/drain regions, a high impurity concentration region and a low impurity concentration region. The trench type element isolation is positioned being in contact with the side surface. The gate electrode extends, across the main surface, in a first direction being parallel with the main surface. The channel region is placed in the main surface, facing with the gate electrode. The source/drain regions are placed in the main surface, putting the channel region between. The high impurity concentration region is placed in the side surfaces which intersects the first direction, includes two gate electrode facing parts which face with the gate electrode and moreover, face with each other in the first direction putting the channel region between, and has impurities of a similar conductivity type to the channel region at a higher concentration than that in a center part of the channel region. The low impurity concentration region is placed in regions where the high impurity concentration region is not formed in the side surface, and a concentration of the impurity is lower than that of the high impurity concentration region.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view for describing a semiconductor device according to a preferred embodiment 1.

FIG. 2 is a drawing for describing a semiconductor device according to the preferred embodiment 1.

FIG. 3 is a plane view for describing an active region according to the preferred embodiment 1.

FIGS. 4 and 5 are both plane views for describing the semiconductor device according to the preferred embodiment 1.

FIGS. 6 and 7 are both cross sectional views for describing a manufacturing method of the semiconductor device according to the preferred embodiment 1.

FIG. 8 is a plane view for describing the manufacturing method of the semiconductor device according to the preferred embodiment 1.

FIGS. 9 to 13 are all cross sectional views for describing the manufacturing method of the semiconductor device according to the preferred embodiment 1.

FIGS. 14 and 15 are both graphs for describing the semiconductor device according to the preferred embodiment 1.

FIG. 16 is a plane view for describing a semiconductor device according to a preferred embodiment 2.

FIG. 17 is a plane view for describing an active region according to the preferred embodiment 2.

FIG. 18 is a plane view for describing the semiconductor device according to the preferred embodiment 2.

FIG. 19 is a graph for describing the semiconductor device according to the preferred embodiment 2.

FIG. 20 is a plane view for describing a semiconductor device according to a preferred embodiment 3.

FIG. 21 is a plane view for describing an active region according to the preferred embodiment 3.

FIG. 22 is a plane view for describing the semiconductor device according to the preferred embodiment 3.

FIG. 23 is a plane view for describing a semiconductor device according to a preferred embodiment 4.

FIG. 24 is a plane view for describing a manufacturing method of the semiconductor device according to the preferred embodiment 4.

FIG. 25 is a plane view for describing a semiconductor device according to a preferred embodiment 5.

FIGS. 26 and 27 are both plane views for describing a manufacturing method of the semiconductor device according to the preferred embodiment 5.

FIG. 28 is a plane view for describing an active region according to a modification example of the preferred embodiments 1 to 5.

### DESCRIPTION OF THE PREFERRED EMBODIMENTS

Preferred Embodiment 1

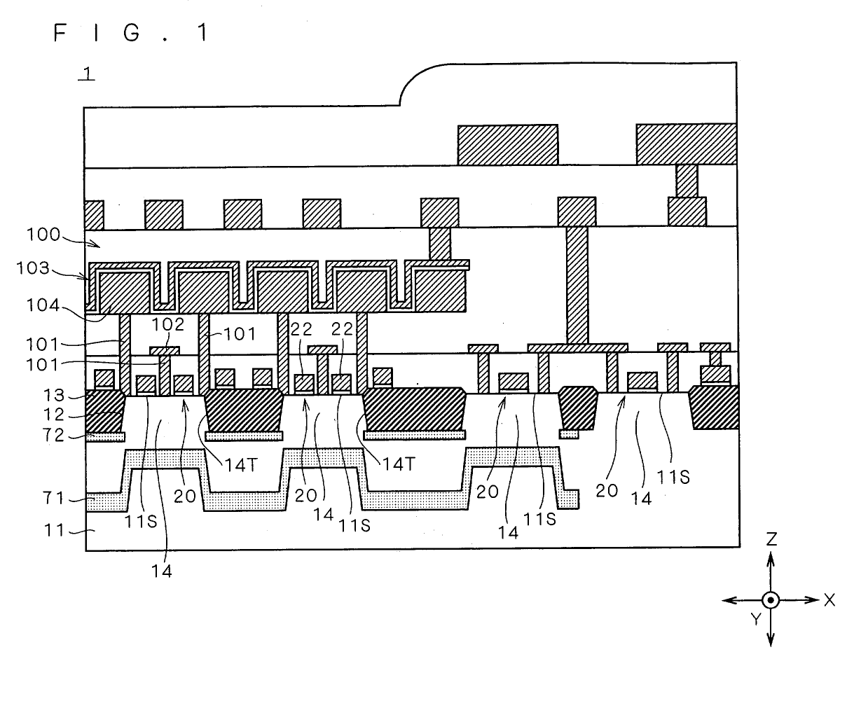

A cross sectional view to describe a DRAM (Dynamic Random Access Memory) as a semiconductor device 1 according to the preferred embodiment 1 is illustrated in FIG. 1. Besides, in FIG. 1, a left half is a memory cell region and a right half is a peripheral circuit region.

In the semiconductor device 1, a trench 12 is formed in a semiconductor substrate 11 (here, a P type silicon substrate is described as a example), and plural active regions 14 are divided by that trench 12. In the trench 12, a trench type element isolation 13 is placed, being in contact with side surfaces 14T of the plural active regions 14, and each active region 14 is separated by the element isolation 13.

Besides, in the substrate 11, a channel cut layer 72 is formed, being in contact with a bottom part of the element isolation 13. Moreover, a retrograde well 71 is formed in a deeper position than the channel cut layer 72, and that retrograde well 71 is formed in a certain distance in depth from a main surface 11S of the substrate 11 (in other words, a main surface of the active region 14) and an inside surface of the trench 12 and has a shape along an irregularity that the main surface 11S and the inside surface described above form.

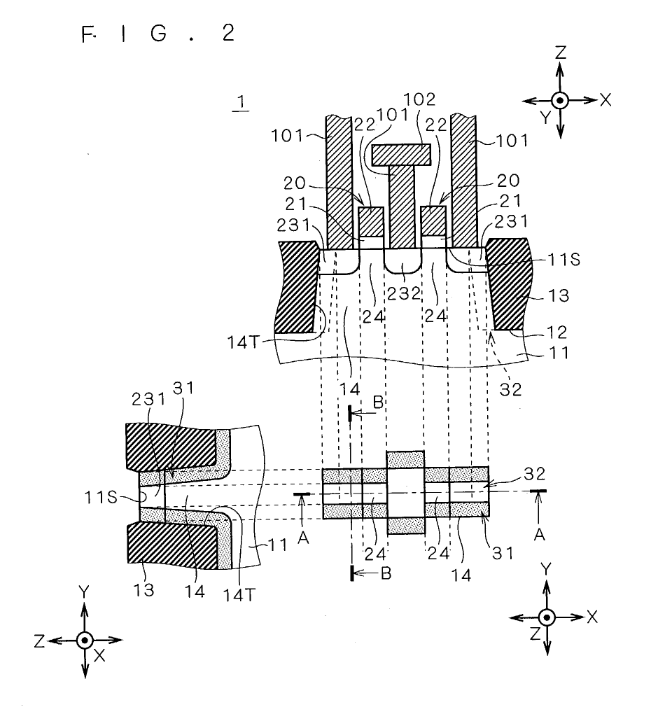

Then, on the main surface 11S, gate oxide films 21 and gate electrodes 22 (refer to FIG. 2 described hereinafter) of MOSFETs (Metal-Oxide-Semiconductor Field Effect Transistors) 20 are placed in this order, and in the main surface 111S, source/drain regions 231 and 232 (refer to FIG. 2) of the MOSFET 20 are placed. Besides, by reason of avoiding a complication of the drawing, the illustration of the source/drain regions 231 and 232 are omitted in FIG. 1.

An interlayer film 100 (of a multilayer structure) is positioned on the substrate 11 covering the MOSFETs 20, and in this interlayer film 100, wirings 102, capacitors 103 for holding memory, plugs 101 and so on are positioned.

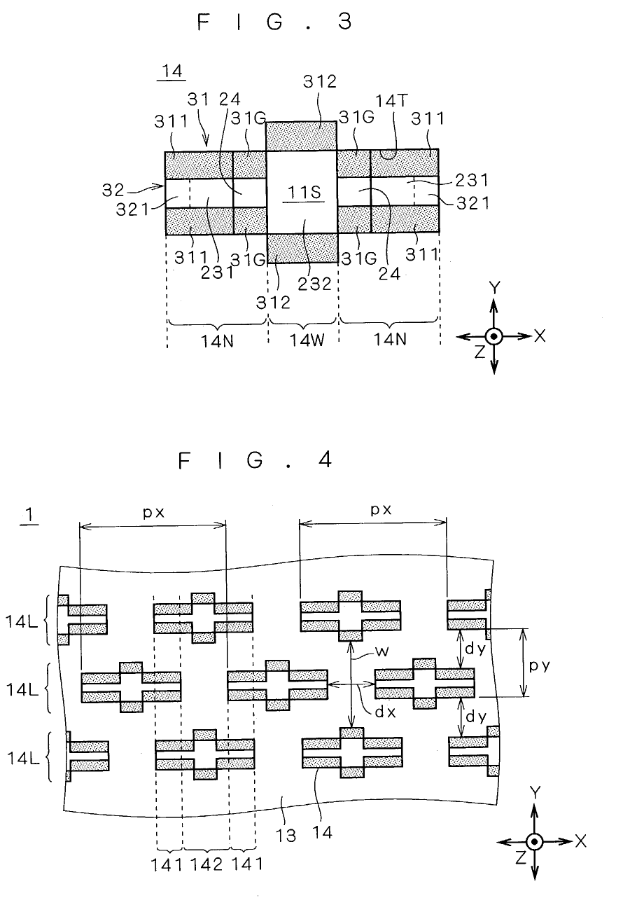

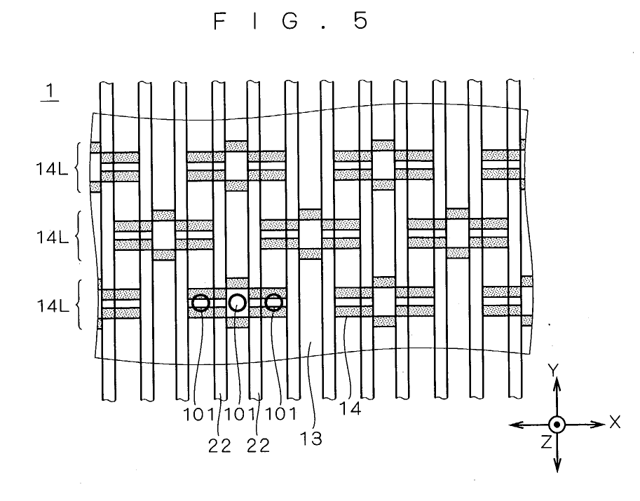

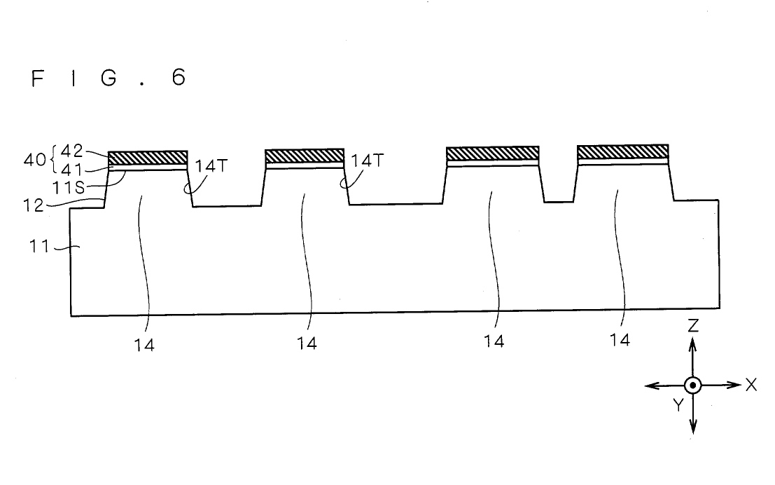

Next, a structure in the memory cell region (refer to the left half of FIG. 1) with regard to the semiconductor device 1 is described referring to FIGS. 2 to 5. FIG. 2 is a drawing for describing a structure with regard to one active region 14 in the memory cell region, and a plane view and cross sectional views at an A-A line and a B-B line in that plane view are illustrated correlating with each other. The cross sectional view at the A-A line corresponds to an extension view of FIG. 1. Besides, by reason of avoiding a complication of the drawings, part of elements at the A-A line in the cross sectional view is omitted in the plane view and the cross sectional view at the B-B line. FIG. 3 is a plane view with regard to the active region 14. FIGS. 4 and 5 are plane views (layout views) for describing a position of the active regions 14 in the memory cell region, and by reason of the description, the gate electrodes 22 of the MOSFETs 20 are transparently illustrated in FIG. 5. Besides, part of the plugs 101 are illustrated in FIG. 5.

Here, an X direction (or a second direction) is determined in a direction which runs at right angles to an extending direction of the gate electrode 22 (parallel with the main surface 11S) and moreover parallel with the main surface 11S of the active region 14, a Y direction (or a first direction) is determined in the extending direction of the gate electrode 22, and a Z direction (or a third direction) is determined being parallel with a direction which runs at right angles to both the X direction and the Y direction, that is to say, a normal direction of the main surface 1S.

First, each active region 14 is described referring to FIG. 2 and FIG. 3. The active region 14 has a figure of a cross extending in the X direction and the Y direction, here. Besides, with regard to that shape, it is determined that a part extending in the Y direction, in other words, a center part in the X direction is described as a wide width part 14W, and parts of both sides of the wide width part 14W, that is to say, two parts whose size in the Y direction is smaller than the wide width part 14W are described as a narrow width part 14N, respectively.

The main surface 11S of the active region 14 is formed of a substrate main surface 11S of the semiconductor substrate 11, that is to say, it is a part of the substrate main surface 11S. According to this, a height level or a position in the Z direction of the main surface 11S are the same between the active regions 14. The active region 14 has a side surface 14T continuing to the main surface 11S, and by intersection of the main surface 11S with the side surface 14T, a rim part or an edge part of the active region 14 is formed.

A high impurity concentration region 31 and a low impurity concentration region 32 are placed in the side surface 14T of the active region 14.

Plural parts (i) being placed in the side surface 14T, being in contact with (reaching) the main surface 11S, (ii) having the same conductivity type (here, a P type) as a channel region or a channel forming region 24 of the MOSFET 20 (a region in the main surface 11S facing with the gate electrode 22) and (iii) that a concentration of an impurity for the P type (boron and indium, for example) is higher than that of a center part of the channel region 24 are named generically as the high impurity concentration region 31. Concretely, as shown in FIG. 3, the high impurity concentration region 31 includes two parts 311 in the respective narrow width parts 14N and two parts 312 in the wide width parts 14W.

The parts 311 and 312 are respectively placed in border parts in the Y direction (in other words, they are placed in parts which intersect the Y direction in the side surface 14T or side surfaces which intersect the Y direction (being parallel with the X direction in the illustrated shape)), the two parts 311 in the respective narrow width part 14N face with each other in the Y direction, and in the same manner, the two parts 312 in the wide width part 14W also face with each other in the Y direction.

Each part 311 in the narrow width part 14N extends right across the wide width part 14W to a part which intersects the X direction in the side surface 14T (being parallel with the Y direction in the illustrated shape). (Each part 311 is in contact with the part.) Besides, the part 311 is in contact with the wide width part 14W.

In the memory cell region, the two MOSFETs 20 are placed to the respective active regions 14, the gate electrodes 22 (which serves as word lines) of the MOSFETs 20 extend in the Y direction across the main surface 11S of the active region 14 and are respectively placed at right both sides of the wide width part 14W in a plane view of the main surface 11S. At this time, the two parts 311 in the respective narrow width parts 14N include respectively a part (a gate electrode facing part) 31G which faces with the gate electrode 22 through the gate oxide film 21 near the wide width part 14W, and the two gate electrode facing parts 31G which face with each other in the Y direction are placed in a border part of the channel region 24, putting the channel forming region 24 between. In other words, a sharing part between the part 311 in the narrow width part 14N and the channel region 24 corresponds to the gate electrode facing part 31G.

Each part 312 in the wide width part 14W is placed in an entire part which intersects the Y direction in the side surface 14T.

Here, in the cross sectional view in FIG. 2, a case that the high impurity concentration region 31 extends in the Y direction to a bottom surface of the trench 12 or a bottom surface of the element isolation 13, being in contact with the element isolation 13 is illustrated, however, there is also a case that the high impurity concentration region 31 does not come near the bottom part of the trench 12 according to a manufacturing condition described hereinafter. However, the high impurity concentration region 31 reaches the main surface 11S of the active region 14, and it is placed in the edge part (of the main surface uS) of the active region 14, at least. Besides, the illustration of the channel cut layer 72 (refer to FIG. 1) is omitted in FIG. 2.

On the other hand, plural parts (i) being placed in regions where the high impurity concentration region 31 is not formed in the side surface 14T (besides, being placed in the side surface 14T, being in contact with (reaching) the main surface 11S), (ii) that a concentration of the impurity described above in the high impurity concentration region 31 is lower than that of the high impurity concentration region 31 are named generically as the low impurity concentration region 32. Concretely, as shown in FIG. 3, the low impurity concentration region 32 includes a part (or a first part) 321 in the respective narrow width parts 14N, the part 321 is placed in a border part in the X direction in the active region 14 (in other words, it is placed in a part which intersects the X direction in the side surface 14T or a side surface which intersects the X direction (being parallel with the Y direction in the illustrated shape)), and these two parts 321 face with each other in the X direction. In the respective narrow width parts 14N, the part 321 is put between the two parts 311 described above in the high impurity concentration region 31 (in the side surface 14T, it is placed between the two parts 311).

Furthermore, in the main surface 11S, the source/drain regions 231 and 232 which have an opposite conductivity type (here, a N type) to the substrate 11 is positioned putting the channel region 24 of the MOSFET 20 between. Here, the source/drain region 231 is placed in the respective narrow width parts 14, and the source/drain region 232 is placed in the wide width part 14W.

Besides, the source/drain region 232 in the wide width part 14W is shared by the two MOSFETs 20. Moreover, as shown in FIG. 1 and FIG. 2, the source/drain region 231 in the narrow width part 14N is connected with a storage node 104 of the capacitor 103 through the plug 101, and the source/drain region 232 in the wide width part 14W is connected with the wiring 102 which serves as the bit line through the plug 101.

As shown in FIG. 2 and FIG. 3, the source/drain region 231 in the narrow width part 14N is entirely placed in the side of the channel region 24 and in contact with the side surface 14T (in contact with the element isolation 13). According to this, that source/drain region 231 overlaps with both the two parts 311 of the high impurity concentration region 31 and the part 321 of the low impurity concentration region 32 at their border parts each other. At this time, while the source/drain region 231 forms a high concentration PN junction with the parts 311 of the high impurity concentration region 31, it does not form such a high concentration PN junction with the parts 321 of the low impurity concentration region 32. In the same manner, the source/drain region 232 in the wide width part 14W is entirely placed in the side of the channel region 24 and in contact with the side surface 14T (in contact with the element isolation 13). According to this, that source/drain region 232 overlaps with the two parts 312 of the high impurity concentration region 31 at their border parts each other. At this time, the source/drain region 232 forms a high concentration PN junction with the parts 312 of the high impurity concentration region 31.

Next, a position of the active regions 14 in the memory cell region is described referring further to FIG. 4 and FIG. 5. The plural active regions 14 in the memory cell region are positioned regularly. In detail, the plural active regions 14 are positioned to make plural rows 14L (extending in the X direction and further being arranged in the Y direction). Besides, the rows 14L are arranged at a pitch py in the Y direction. The active regions 14 in the respective rows 14L form in line in the X direction at a distance dx and furthermore at a pitch px, however, between two continuing arbitrary rows 14L (in other words, two arbitrary adjacent rows 14L), the active regions 14 are shifted to the X direction at a half of the pitch px of the X direction. At this time, each active region 14 has such a size in the X direction as to face with the active region 14 in the adjacent row 14L and the active region 14 in furthermore the adjacent row 14L (that is to say, the row 14L putting the other row 14L between).

Concretely, center parts 142 of the active regions 14 in the X direction do not face with each other in the Y direction between the two continuing arbitrary rows 14L, however, they face with each other between every second rows 14L (in other words, between the rows 14L of both sides in the three continuing arbitrary rows 14L, or between the rows 14L in order of even numbers and between the rows 14L in order of odd numbers). Moreover, parts 141 of both sides of the part 142 in respective active regions 14 face with each other in the Y direction between the two continuing arbitrary rows 14L.

Here, as recognized from a comparison among FIGS. 3 to 5, each of the parts 142 facing with each other every second row includes the wide width part 14W and parts where the gate electrodes 22 face in the active region 14 (parts which have the channel region 24). Moreover, the each of parts 141 which face with each other between the adjacent rows 14L includes a part excluding the part described above that the gate electrode 22 faces in the narrow width part 14N. Besides, as obviously known from a manufacturing method described hereinafter, with regard to the semiconductor device 1, each of the parts 141 which faces with each other between the adjacent rows 14L may include the part that the gate electrode 22 faces.

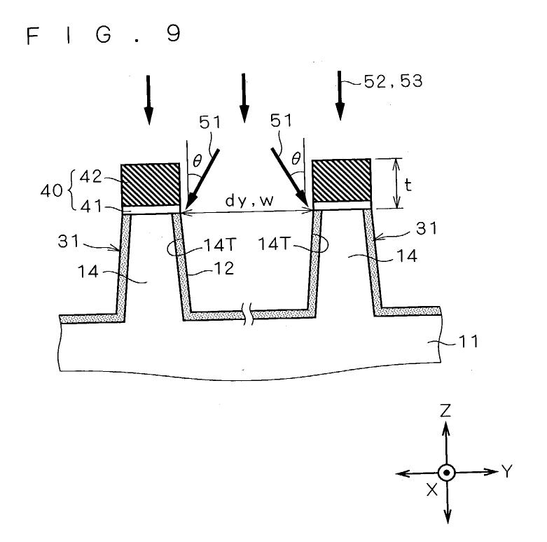

As described above, the active regions 14 in the respective rows 14L form in line in the X direction at the distance dx and furthermore at the pitch px, and the plural rows 14L are arranged in the Y direction at the pitch py. Moreover, the parts 141 which face with each other between the adjacent rows 14L are arranged in the Y direction at the distance dy and further at the pitch py, the same as the pitch between the rows 14L. Moreover, with regard to the distance in the Y direction between the parts 142 facing with each other every second row, the distance between the parts described above facing with the gate electrodes 22 is described as (dy+py), and a distance w between the wide width parts 14W is shorter than the distance (dy+py). Here, the sizes dx, dy, w, px and py are determined to be the sizes near the main surface 11S, that is to say, near an aperture entrance of the trench 12 (refer to FIG. 9 hereinafter).

Besides, as described above, the active regions 14 are shifted to the X direction at a half of the pitch px in the X direction between the two continuing arbitrary rows 14L, thus it can be considered that the active regions 14 form in lines in the X direction and also form in lines in the direction inclined at 45° toward the X direction (the inclined direction runs at right angles to the Z direction). Or, it can also be considered that the active regions 14 in the memory cell region are composed of the active regions 14 positioned as a matrix and the active regions 14 that the matrix-arranged active regions 14 are shifted to the direction inclined at 45° described above.

As described already, the two MOSFETs 20 are placed in the respective active regions 14 in the memory cell region. At this time, the gate electrodes 22 in the memory cell region forming in line in the Y direction are connected successively, and make one long gate electrode 22. Conversely speaking, the MOSFETs 20 forming in line in the Y direction share one long gate electrode 22, and parts facing with the active regions 14 (and their peripheral parts) in that one long gate electrode 22 make the gate electrode 22 of the corresponding MOSFET 20, respectively.

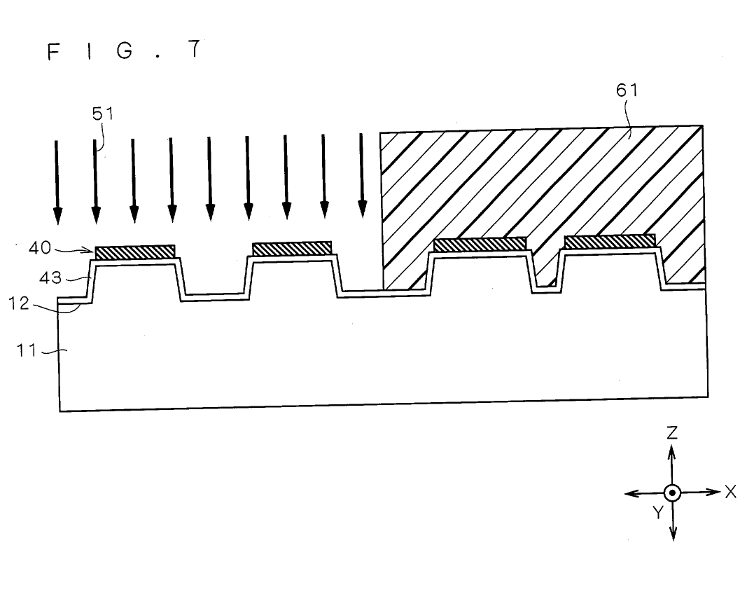

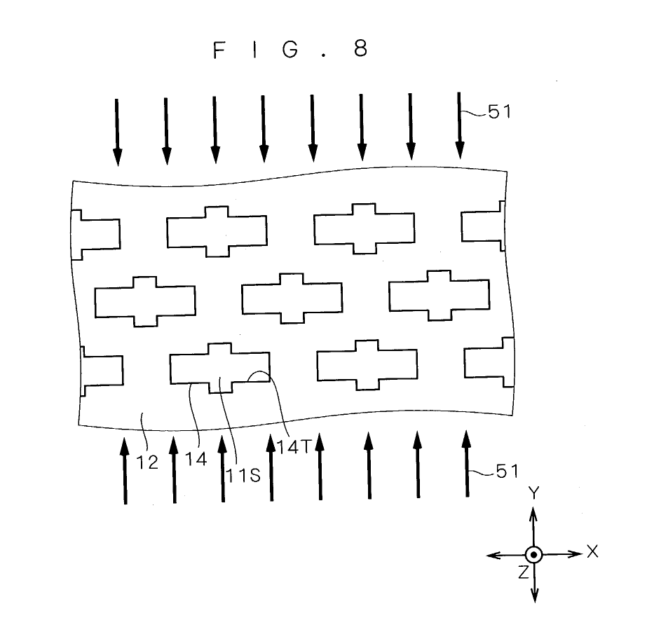

Next, a manufacturing method of the semiconductor device 1, mainly a forming method of the high impurity concentration region 31, is described referring the cross sectional views and the plane views of FIGS. 6 to 13, also. The cross sectional views in FIG. 6 and so on correspond to the cross sectional view at the A-A line in FIG. 2.

First, a patterning mask 40 which has a plane pattern corresponding to the active regions 14 positioned as described above is formed on the main surface (or the substrate main surface) 11S of the substrate 11 composed of the P type silicon (refer to FIG. 6). In detail, for example, a silicon oxide film 41 in a thickness of appropriately 10 to 30 nm is formed by a thermal oxidation on the substrate main surface 11S, and a silicon nitride film 42 in a thickness of appropriately 100 to 200 nm is deposited on that oxide film 41. Moreover, by removing (opening) a part corresponding to the element isolation 13 in the nitride film 42 and the oxide film 41 using a photolithography technique and an etching technique, the nitride film 42 and the oxide film 41 are processed to be a plane pattern corresponding to the active regions 14 positioned as described above. According to this, the patterning mask 40 which is composed of both the patterned films 41 and 42 is obtained.

Moreover, an etching is performed on the substrate 11 through the pattering mask 40, and the trench 12 in a depth of approximately 200 to 300 nm is formed (refer to FIG. 6). According to this, the plural active regions 14 are formed in the substrate 11 (refer to FIG. 6). Besides, by reason that the main surfaces 11S of the respective active regions 14 are formed from the substrate main surface 11S, the main surfaces 11S of the active regions 14 are placed in the same level in the Z direction. Afterwards, for example, by a thermal oxidation on a surface exposed in the trench 12 (including the side surfaces 14T of the active regions 14), a silicon oxide film 43 in a thickness of 5 to 30 nm is formed in the trench 12 (refer to FIG. 7).

Next, after covering the peripheral circuit region with a resist mask 61, boron, for example, as impurities 51 for the P type is implanted in a condition of 10 to 30 keV and 4×10¹² to 4×10¹³/cm² in a condition of having the patterning mask 40 (refer to FIGS. 7 to 9). Particularly, an ion implantation of the impurities 51 is performed from the only directions which run at right angles to the X direction and further are inclined at a certain angle θ toward the Z direction (there is two directions that satisfy this condition). Besides, it can be considered that each implanting direction is parallel with the Y direction in the plane view of the main surface 11S, in other words, each implanting direction has a component of the Y direction. Here, when a thickness of the patterning mask 40 (a size in the Z direction) is described as t, the angle θ described above is set to satisfy θ<tan⁻¹ (dy/t). At this time, the ion implantation can be performed simultaneously or in order from the two directions described above.

By raising the impurity concentration as compared with the substrate 11 by that oblique ion implantation or the implantation from the two directions, the parts 311 and 312 described above of the high impurity concentration region 31 (refer to FIG. 3) are formed in the side surface 14T being in contact with the main surface 11S.

At this time, by the selection of the implanting direction described above, the ion implantation of the impurities 51 can be performed to the parts intersecting the Y direction in the side surface 14T, and moreover, it is possible to suppress or arrest the ion implantation of the impurities 51 to the parts intersecting the X direction in the side surface 14T. According to this, the low impurity concentration region 32 (refer to FIG. 3) can be formed. Moreover, by the selection of the implanting angle θ described above, the ion implanting of the impurities 51 can be performed to both the parts 141 which face with each other between the adjacent rows 14L and the parts 142 which face with each other every second row (refer to FIG. 4).

Afterwards, the ion implantation of boron, for example, as impurities 52 (refer to FIG. 9) for the retrograde well 71 (refer to FIG. 1) is performed from the Z direction with an accelerating energy or an implantation energy which goes through the patterning mask 40. Moreover, the ion implantation of boron, for example, as impurities 53 (refer to FIG. 9) for the channel cut layer 72 (refer to FIG. 1) is performed from the Z direction with an accelerating energy which does not go through the patterning mask 40.

At this time, an implantation order of the impurities 51 to 53 is not concerned. Moreover, the implantation of a few of the impurities 51 to 53 simultaneously can also be applicable. Besides, all of the implanting directions of the impurities 51 to 53 run at right angles to the X direction (refer to FIG. 9), and the ion implantation processes of the impurities 51 to 53 are performed from the only directions which run at right angles to the X direction.

Besides, the ion implantation of the impurities 52 and 53 simultaneously can also be performed to the regions which form a N type MOSFETs in the peripheral circuit region. According to this, it becomes possible to prevent the impurities 53 for the channel cut layer 72 from entering the active region 14 of the N type MOSFET forming region, and thus a junction leakage is reduced. Besides, in case that the ion implantation of the impurities 52 and 53 is performed to the memory cell region and the peripheral circuit region separately, the implantation condition can be optimized for each region.

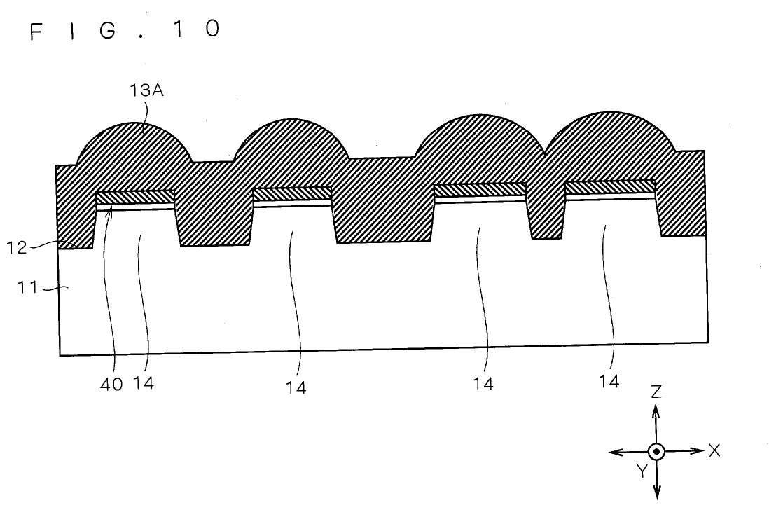

Next, a silicon oxide film (or an insulating film) 13A which is to be the element isolation 13 afterwards in a thickness of approximately 300 to 600 nm is deposited, and then the trench 12 is imbedded by that oxide film 13A (refer to FIG. 10). Besides, in the illustration of FIG. 10 and so on, the oxide film 43 in FIG. 7 is included in the oxide film 13A. Afterwards, an anneal is performed at a temperature of approximately 900° C. to 1100° C., for example.

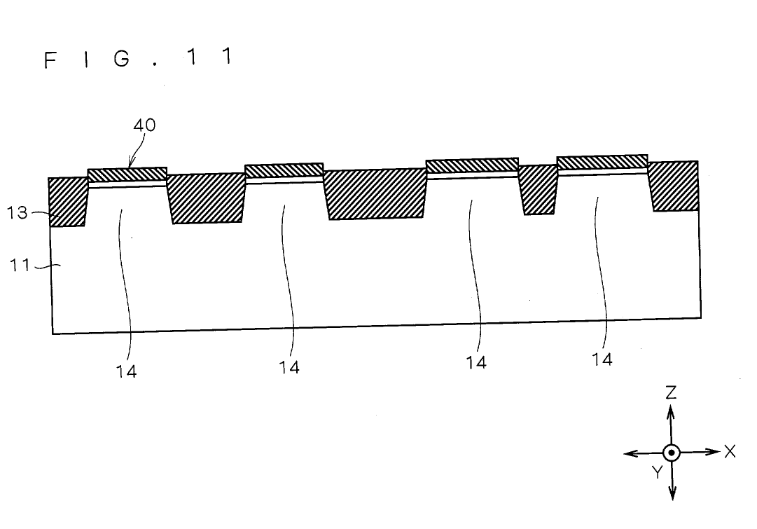

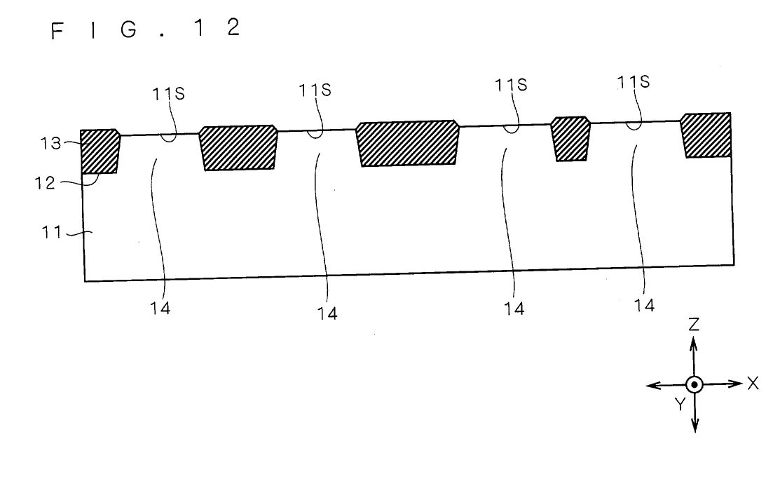

Then, the oxide film 13A described above is flatted by a CMP (Chemical Mechanical Polishing) method, a dry etching, a wet etching, or using them simultaneously, and then a part on the patterning mask 40 is removed (refer to FIG. 11). Then, by removing the nitride film 42 and the oxide film 41 successively, the element isolation 13 is completed (refer to FIG. 12).

Afterwards, by the ion implantation from the Z direction, a well which is not shown is formed in a certain region in the substrate 11. Besides, the ion implantation at this time can also be performed simultaneously with the ion implantation for the high impurity concentration region 31 described above.

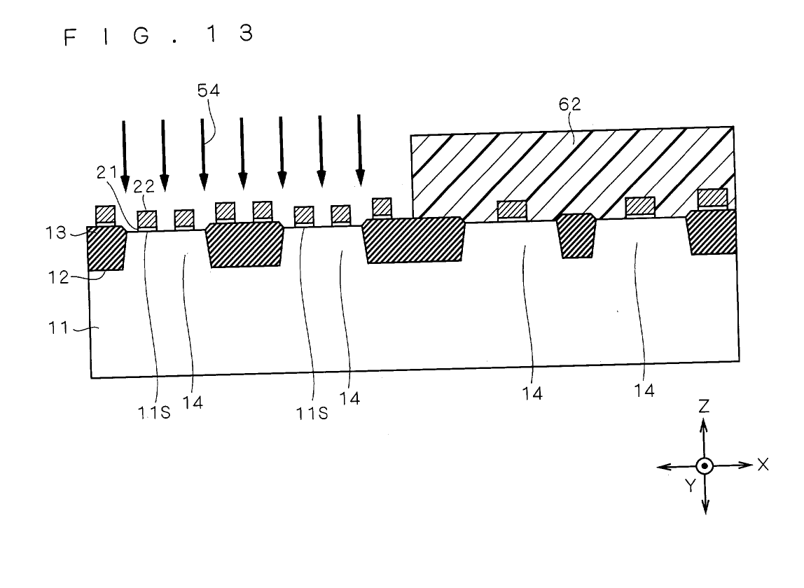

Then, the MOSFET 20 is formed on each active region 14. Concretely, the gate oxide film 21 and the gate electrode 22 are formed by forming the silicon oxide film and the conductive film successively on the main surface 11S of the active region 14 and patterning both the films (refer to FIG. 13). At this time, in the memory cell region, the patterning described above is performed so that the gate electrode 22 extends in the Y direction facing with (the gate electrode facing parts 31G of) the high impurity concentration region 31 of the active region 14 and the element isolation 13. Next, after covering the peripheral circuit region with the resist mask 62, an ion implantation of phosphorus, for example, as impurities 54 for the N type is performed from the Z direction in a condition of 10 to 30 keV and 1×10¹³ to 1×10¹⁵/cm² (refer to FIG. 13). At this time, the source/drain regions 231 and 232 are formed in a self-aligned manner by performing an ion implantation of the impurities 54 to the main surfaces 11S of the plural active regions 14 using the gate electrodes 22 and the gate oxide films 21 as a mask. According to such an ion implantation, the source/drain regions 231 and 232 are formed to be in contact with the element isolation 13, thus the source/drain region 231 can be formed overlapping with the high impurity concentration region 31 and the low impurity concentration region 32, and the source/drain region 232 can be formed overlapping with the high impurity concentration region 31.

Furthermore, by forming the plugs 101, the wirings 102, the capacitors 104, the interlayer film 100 and so on, the semiconductor device 1 shown in FIG. 1 is completed.

According to the semiconductor device 1, the effect described in the following can be obtained.

First, the inverse narrow channel effect is suppressed by the gate electrode facing part 31G of the high impurity concentration region 31, and for example, as shown in FIG. 14, a characteristic that the threshold value of the MOSFET 20 depends on the channel width improved. According to this, even if a reduction of the MOSFET 20 is promoted, the characteristic can be maintained, that is to say, the further miniatualization of the MOSFET 20 is practicable.

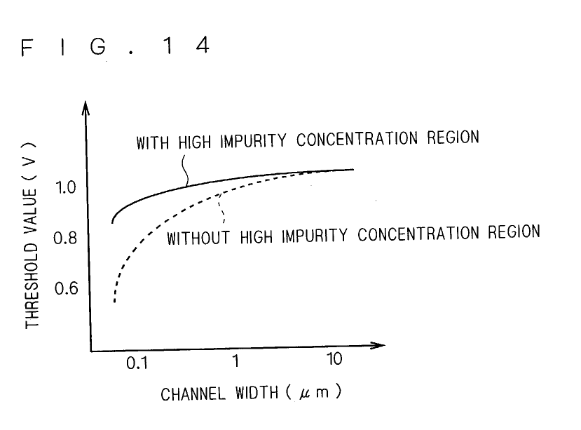

Furthermore, the part 321 of the low impurity concentration region 32 is placed in the border part of the active region 14 in the X direction (in other words, the source/drain region 231 placed in the narrow width part 14N overlaps with the low impurity concentration region 32 at the respective border parts), thus as compared with the conventional structure that the high impurity concentration region is formed on the entire edge part of the active region, that is to say, the entire rim part and the low impurity concentration region 32 is not included, a high concentration PN junction which the source/drain region 231 and the high impurity concentration region 31 form can be lessened. Accordingly, as shown in a graph of FIG. 15, the junction leakage current between the source/drain region and the substrate 11 can be suppressed, and the consumed power can be reduced. At this time, by suppressing the junction leakage current, the leakage current from the storage node 104 of the capacitor 103 (refer to FIG. 1) is suppressed, thus a refresh characteristic of the DRAM is improved.

Moreover, according to the semiconductor device 1, both the inverse narrow channel effect and the junction leakage current can be suppressed simultaneously.

In addition, as described above, the source/drain region 231 in the narrow width part 14N overlaps with the low impurity concentration region 32, thus by reason of the presence of the low impurity concentration region 32, an effective impurity concentration of the source/drain region 231 can be raised as compared with the conventional structure that the low impurity concentration region 32 is not included. According to this, a resistance of the source/drain region 231 is decreased. Furthermore, a contact resistance between the source/drain region 231 and the plug 101 is decreased. As a result, by the decrease of these resistance, a current driving capability of the MOSFET 20 is improved.

Moreover, according to the ion implanting condition for the high impurity concentration region 31 described above, the low impurity concentration region 32, concretely, the part 321 can be formed in the part which intersects the X direction in the side surface 14T of the active region 14. At this time, the implanting angle θ and the implanting direction are set using a regularity of the position of the active regions 14, thus the semiconductor device 1 which has the effect described above can be manufactured by a simple method.

It is considered that the high impurity concentration region 31 and the low impurity concentration region 32 are formed using a mask. However, in a minute DRAM, forming a mask that only parts corresponding to the high impurity concentration regions 31 are opened accompanies a great difficulty both in a point of a size control and in a point of a superposition control to the active region 14, and causes an increase in a cost by reason of an increase of the number of masks.

In contrast with this, according to the manufacturing method described above, the high impurity concentration region 31 and the low impurity concentration region 32 can be formed without using the mask. At this time, the increase in the cost by reason of using the mask is not occurred.

Besides, according to the implanting condition described above, the ion implantation of the impurities 51 can be performed both to the parts 141 facing with each other between the adjacent rows 14L and to the parts 142 facing with each other every second row, thus even in case that the active region 14 has a size and a shape that the part which the gate electrode 22 faces with (the part which has the gate electrode facing part 31G) is included in the parts 141 facing with each other between the adjacent rows 14L, the high impurity concentration region 31 can be formed.

Moreover, in the manufacturing method described above, the anneal is performed after the silicon oxide film 13A for the element isolation 13 is embedded in the trench 12, thus the stress by embedding the silicon oxide film is relaxed, and as a result, the junction leakage current can be further suppressed.

Furthermore, by using indium as the impurities 51 for the high impurity concentration region 31, a sharp impurity distribution can be obtained as compared with a case of using boron. That is to say, by using indium, the inverse narrow channel effect can be suppressed to the same degree with the less implantation amount than the case of using boron. According to this, by the decrease of the implantation amount, the junction leakage current can be further suppressed. Moreover, by using indium as the impurities 53 for the channel cut layer 72, the similar effect can be obtained.

As described above, both the ion implantation for the high impurity concentration region 31 and the ion implantation for the retrograde well 71 and/or for the channel cut layer 72 can also be performed simultaneously, and in such a case, the time required for the manufacture can be shortened. Moreover, according to the ion implanting condition for the channel cut layer 72 described above, it is possible to prevent the impurities 53 from being implanted in the active region 14 by using the patterning mask 40. According to this, the junction leakage current can be further suppressed.

Preferred Embodiment 2.

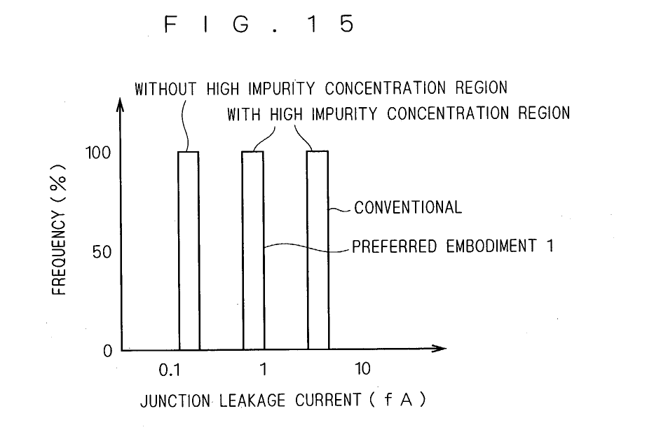

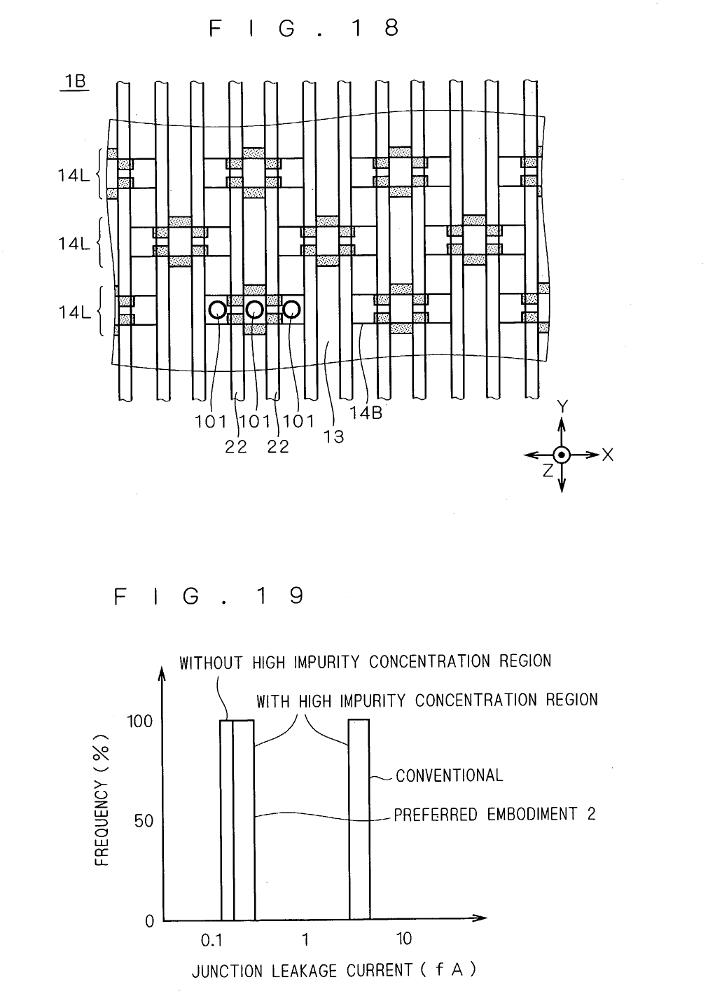

In the manufacturing method of the preferred embodiment 1, by setting the implanting angle θ (refer to FIG. 9) as to satisfy tan⁻¹(dy/t)<θ<tan⁻¹{(dy+py)/t} and further setting the implanting direction to the two directions described above, a semiconductor device 1B which includes active regions 14B as shown in plane views of FIGS. 16 to 18 is obtained.

Each active region 14B has the same shape as the active region 14 and is placed in the same manner in a memory cell region in the semiconductor device 1B.

A high impurity concentration region 31B of the active region 14B includes parts 313 in the narrow width parts 14N and the parts 312 in the wide width part 14W. Besides, the part 312 of the high impurity concentration region 31B is placed in the same manner as the high impurity concentration region 31.

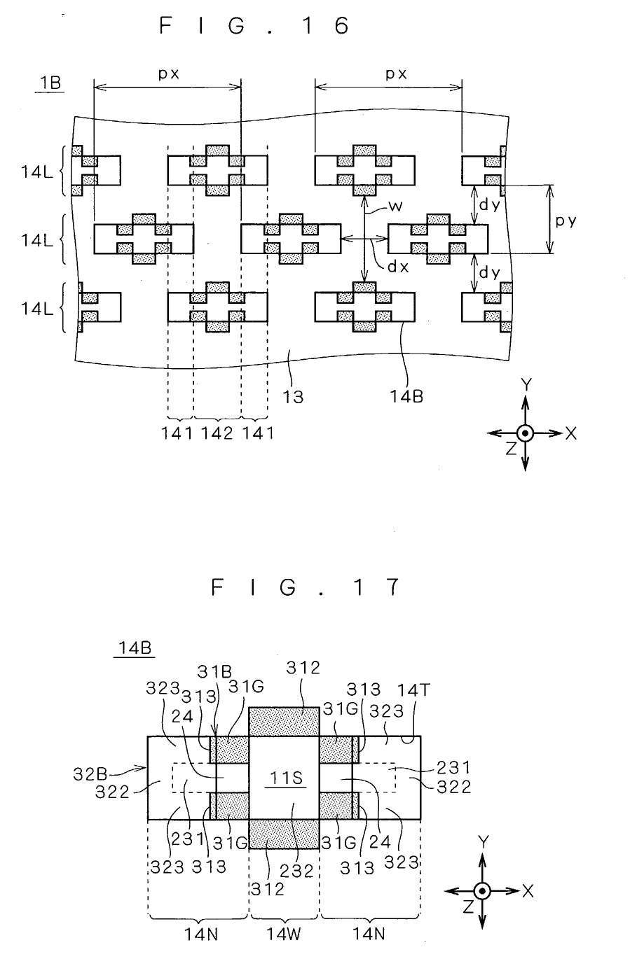

As recognized from the references of FIG. 17 and FIG. 3, the part 313 in the narrow width part 14N has a shape that the part 311 of the high impurity concentration region 31 described already is shortened in the X direction. Concretely, that part 313 extends right across the wide width part 14W to the position beyond the channel region 24 a little in the X direction, however, it does not reach (is not in contact with) the part which intersects the X direction in the side surface 14T. Besides, in the same manner as the part 311 described above, the two parts 313 are placed facing with each other in the Y direction in the narrow width part 14N, and the respective parts 313 includes the gate electrode facing part 31G in proximity to the wide width part 14W.

On the other hand, a low impurity concentration region 32B of the active region 14B includes one part (or a first part) 322 and two parts (or two second parts) 323 in the respective narrow width parts 14N. Concretely, the part 322 is placed in the border part in the X direction in the active region 14B (in other words, it is placed in the part which intersects the X direction in the side surface 14T or in the side surface which intersects the X direction), and extends in the Y direction and reaches (is in contact with) the part which intersects the Y direction in the side surface 14T. The two parts 323 are respectively placed in the border part in the Y direction in the active region 14B (in other words, they are respectively placed in the parts which intersect the Y direction and face with each other in the side surface 14T or in the side surfaces which intersect the Y direction), and those two parts 323 face with each other in the Y direction. The respective parts 323 extend in the X direction and reaches (is in contact with) the part which intersects the X direction in the side surface 14T and the part 313 of the high impurity concentration region 31. Besides, these parts 322 and 323 share the border part mutually. As shown in FIG. 16, the parts 322 and 323 of the low impurity concentration region 32B are placed in each of the parts 141 which face with other in the Y direction between the adjacent rows 14L.

In the active region 14B, the source/drain regions 231 and 232 are placed in the same manner as the active region 14 in FIG. 3 described already. At this time, corresponding to the high impurity concentration region 31B and the low impurity concentration region 32B, the source/drain region 231 overlaps with the two parts 313 of the high impurity concentration region 31B and the parts 322 and 323 of the low impurity concentration region 32B at the border parts each other. Besides, in the same manner as the active region 14 in FIG. 3, the source/drain region 231 forms the high concentration PN junction with the parts 313 of the high impurity concentration region 31B, however, it does not form such a high concentration PN junction with the parts 322 and 323 of the low impurity concentration region 32B. Besides, the part 313 of the high impurity concentration region 31B can be placed being in contact with the source/drain region 231.

Besides, in the wide width part 14W of the active region 14B, a relation between the source/drain region 232 and the part 312 of the high impurity concentration region 31B is similar to the active region 14. Furthermore, the other structure of the active region 14B and the semiconductor device 1B is basically similar to the active region 14 and the semiconductor device 1 described already.

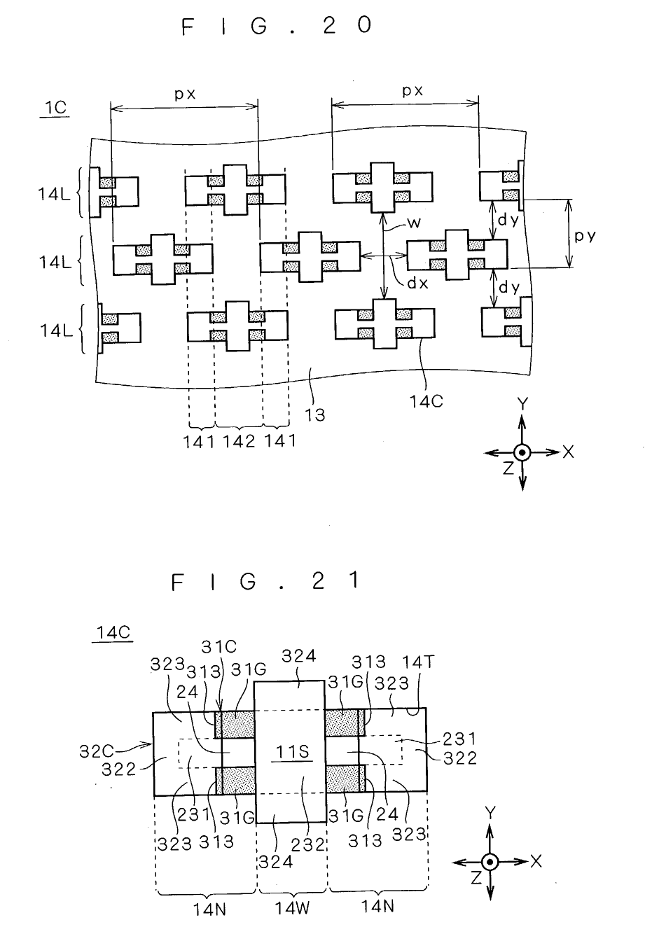

By the presence of the low impurity concentration region 32B, the semiconductor device 1B has the similar effect to the semiconductor device 1 (refer to FIG. 14, for example). Furthermore, according to the setting of the implanting angle θ and the implanting direction described above, the parts 322 and 323 of the low impurity concentration region 32B can be placed in the each of parts 141 which face with each other between the adjacent rows 14L without implanting the impurities 51 for the high impurity concentration region 31B in those parts 141. At this time, the part 313 of the high impurity concentration region 31B is smaller than the part 311 of the high impurity concentration region 31 described already, thus it is possible to make the high concentration PN junction lessen more than the semiconductor device 1. As a result, the junction leakage current can be further suppressed, as shown in the graph of FIG. 19 (also refer to FIG. 15 described already).

Moreover, the effective impurity concentration of the source/drain region 231 in the narrow width part 14N is higher in the semiconductor device 1B by reason of the difference of the size between the low impurity concentration regions 32B and 32. Accordingly, by decreasing further the resistance of the source/drain region 231 and the contact resistance between the source/drain region 231 and the plug 101, the current driving capability of the MOSFET 20 is further improved. At this time, a diameter of the plug 101 which is connected with that source/drain region 231 can become larger than the semiconductor device 1, thus the resistance of that plug 101 can be reduced.

Preferred Embodiment 3.

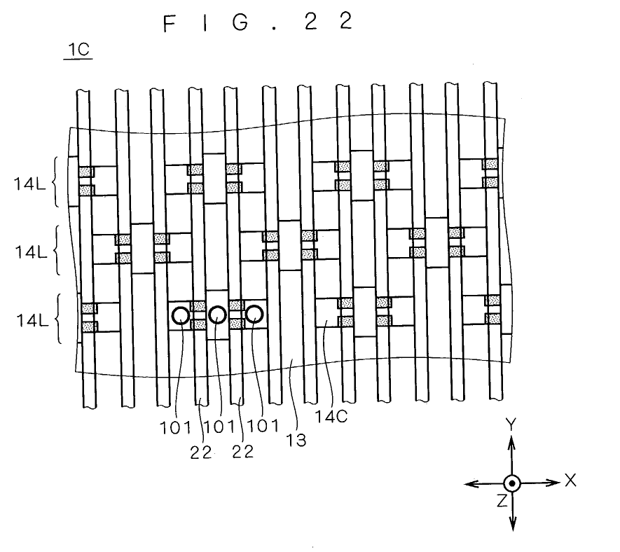

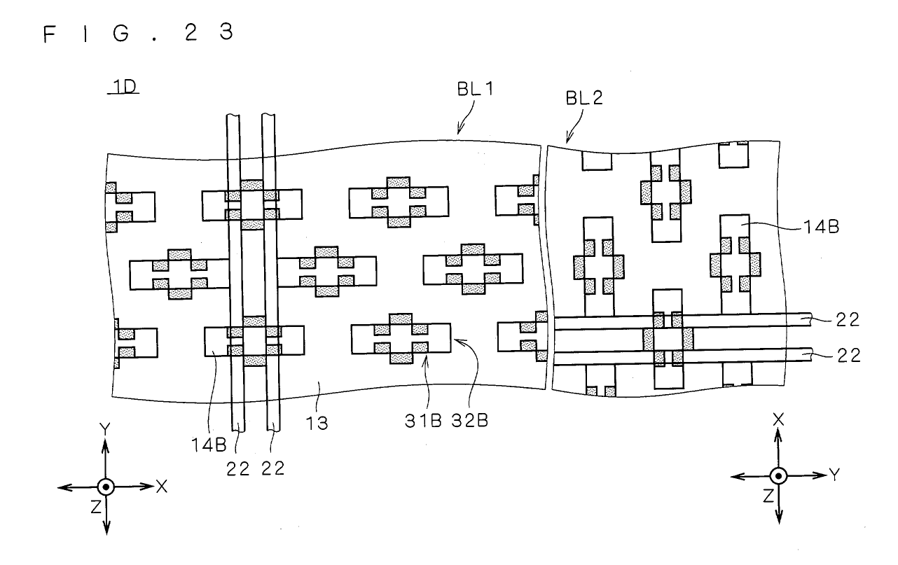

Furthermore, in the manufacturing method of the preferred embodiment 1, by setting the implanting angle θ (refer to FIG. 9) to satisfy tan⁻¹(w/t)<θ<tan⁻¹ {(dy+py)/t} and further setting the implanting direction to the two directions described above, a semiconductor device 1C which includes active regions 14C as shown in plane views of FIGS. 20 to 22 is obtained.

Each active region 14C has the same shape as the active region 14 and is placed in the same manner in a memory cell region of the semiconductor device 1C.

As recognized from the references of FIG. 21 and FIG. 17, the high impurity concentration region 31C of the active region 14C has a structure that the part 312 in the wide width part 14W is eliminated from the high impurity concentration region 31B described already.

On the other hand, a low impurity concentration region 32C of the active region 14C includes two parts (or two second parts) 324 in the wide width part 14W in addition to the part (or the first part) 322 and the two parts (and the two second parts) 323 of the low impurity concentration region 32B described already. Those two parts 324 are placed instead of the part 312 of the high impurity concentration region 31B in FIG. 17, and concretely, they are respectively placed in the border parts in the Y direction in the wide width part 14W (in other words, they are respectively placed in the parts which intersect the Y direction and face with each other in the side surface 14T or in the side surfaces which intersect the Y direction), and those two parts 324 face with each other in the Y direction. Besides, each part 324 is entirely placed in the part which intersects the Y direction in the side surface 14T in the wide width part 14W.

In the active region 14C, the source/drain regions 231 and 232 are placed in the same manner as the active region 14 in FIG. 3 described already. At this time, corresponding to the high impurity concentration region 31C and the low impurity concentration region 32C, the source/drain region 232 in the wide width part 14W overlaps with the parts 324 of the low impurity concentration region 32C at the border parts each other. At this time, the source/drain region 232 does not form the high concentration PN junction with the parts 324 of the low impurity concentration region 32C.

Besides, in the narrow width part 14N of the active region 14C, a relation among the source/drain region 231, the high impurity concentration region 31C and the low impurity concentration region 32C is similar to the active region 14B. Furthermore, the other structure of the active region 14C and the semiconductor device 1C is basically similar to the active region 14 and the semiconductor device 1 described already.

By the presence of the low impurity concentration region 32C, the semiconductor device 1C has the similar effect to the semiconductor devices 1 and 1B (refer to FIG. 14 and FIG. 19, for example). Furthermore, according to the setting of the implanting angle θ and the implanting direction described above, the parts 324 of the low impurity concentration region 32C can be placed in the wide width part 14W without implanting the impurities 51 for the high impurity concentration region 31C in that wide width part 14W. According to this, the concentration PN junction is not formed in the wide width part 14W, thus the junction leakage current between the source/drain region 232 and the substrate 11 in the wide width part 14W can be lessened more than the semiconductor devices 1 and 1B. By suppressing that junction leakage current, the leakage current from the wiring 102 (refer to FIG. 1) which serves as the bit line is suppressed, and the consumed power can be reduced.

Moreover, the effective impurity concentration of the source/drain region 232 in the wide width part 14W is higher in the semiconductor device 1C by reason of the difference of the size among the low impurity concentration regions 32C, 32B and 32. Accordingly, by decreasing the resistance of the source/drain region 232 in the wide width part 232 and the contact resistance between the source/drain region 232 and the plug 101, the current driving capability of the MOSFET 20 is further improved. At this time, a diameter of the plug 101 which is connected with that source/drain region 232 can become larger than the semiconductor devices 1 and 1B, thus the resistance of that plug 101 can be reduced.

Preferred Embodiment 4.

A plane view for describing a semiconductor device 1D according to the preferred embodiment 4 is illustrated in FIG. 23. The semiconductor device 1D includes two blocks BL1 and BL2 in the memory cell region, and there is a relation between the block BL1 and the block BL2 that the X direction and the Y direction are inversed with each other. That is to say, the X direction of the block BL1 is parallel with the Y direction of the block BL2, and the Y direction of the block BL1 is parallel with the X direction of the block BL2.

The block BL1 and BL2 of the semiconductor device 1D include a similar structure to the memory cell region of the semiconductor device 1B described already (refer to FIGS. 16 to 18), respectively. That is to say, the active regions 14B and so on are positioned according to a direction regulation in each of the blocks BL1 and BL2, and there is a relation that a structure in the block BL2 is the same with a structure obtained by rotating that in the block BL1 with 90° on the Z direction. Besides, in FIG. 23, to prevent the complication of the drawing, an illustration of a part of elements is omitted in the same manner as FIGS. 16 to 18, and only a part of the gate electrodes 22 is illustrated.

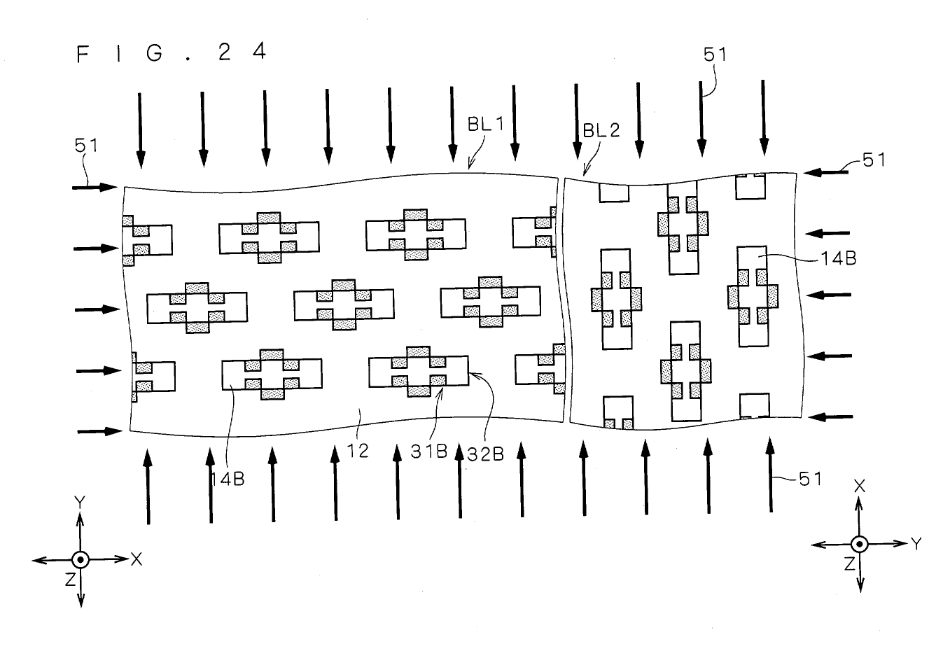

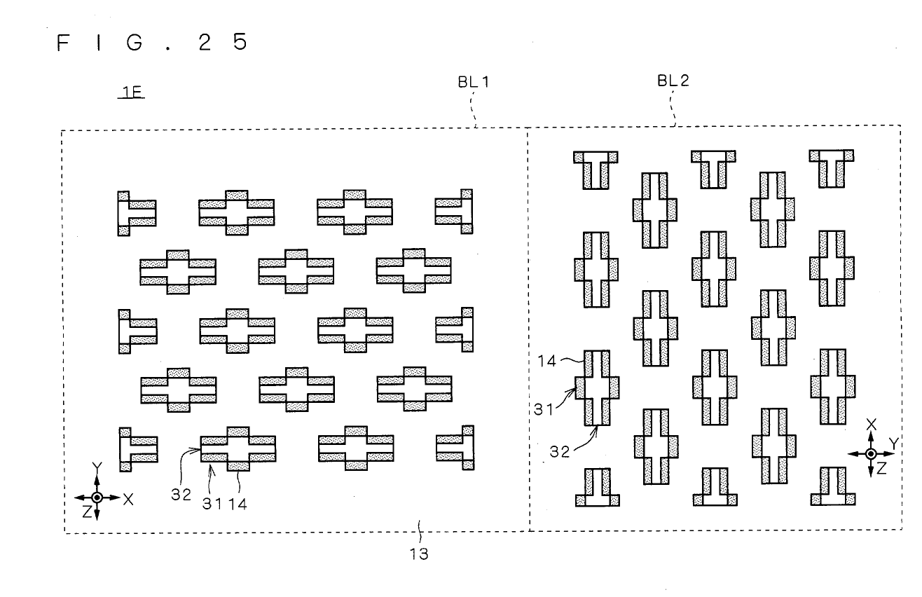

Next, referring to a plane view of FIG. 24, a manufacturing method of the semiconductor device 1D, especially, a manufacturing method of the high impurity concentration region 31B of the semiconductor device 1D is described. Besides, the description here centers on the difference of it from the manufacturing method of the semiconductor devices 1 and 1B.

First, in a forming process of the pattering mask 40 (refer to FIG. 6), openings in the respective blocks BL1 and BL2 are formed according to the direction regulation in each of the blocks BL1 and BL2. Moreover, the trench 12 is formed by the etching through the pattering mask 40, and the active regions 14 are formed in the respective blocks BL1 and BL2.

Moreover, the ion implantation of the impurities 51 to form the high impurity concentration region 31B is performed in the following condition. That is to say, the implanting direction is set to be four directions (refer to FIG. 24), concretely, two directions which run at right angles to the X direction and further, are inclined at the certain angle θ toward the Z direction (refer to FIG. 9), and two directions which run at right angles to the Y direction and further, are inclined at the certain angle θ described above toward the Z direction. Especially, the implanting angle θ is set to satisfy tan⁻¹(dy/t)<θ<tan⁻¹{(dy+py)/t}, and further, tan⁻¹(dx/t)<θ. At this time, the ion implantation can be performed simultaneously from the four directions described above, or the ion implantation can also be performed in order from every two directions facing with each other or every one direction, for example. Besides, the other implanting condition is the same with that of the high impurity concentration region 31 and so on.

At this time, in the same manner as the case of the semiconductor device 1, the ion implantation for the retrograde well 71 (refer to FIG. 1) and/or the ion implantation for the channel cut layer 72 (refer to FIG. 1) can also be performed being simultaneous with the ion implantation for the high impurity concentration region 31B.

With regard to the other process, the manufacturing method of the semiconductor device 1, for example, is applicable.

According to the implanting condition described above for the high impurity concentration region 31B, the high impurity concentration region 31B and the low impurity concentration region 32B can be formed without the mask, and furthermore, simultaneously in both of the blocks BL1 and BL2, even in case of the semiconductor device 1D which has the blocks BL1 and BL2.

Besides, as described above, each of the blocks BL1 and BL2 includes the same structure with the memory cell region of the semiconductor device 1B, thus, according to the semiconductor device 1D, the same effect with the semiconductor device 1B can be obtained.

Preferred Embodiment 5.

A plane view for describing a semiconductor device 1E according to the preferred embodiment 5 is illustrated in FIG. 25. In the same manner as the semiconductor device 1D in FIG. 23, the semiconductor device 1E includes two blocks BL1 and BL2 in the memory cell region. Each of the blocks BL1 and BL2 of the semiconductor device 1E is composed in the same manner as the memory cell region of the semiconductor device 1 (refer to FIGS. 1 to 5) described already. That is to say, the active regions 14 and so on are positioned according to the direction regulation in each of the blocks BL1 and BL2. Besides, in FIG. 25, to prevent the complication of the drawing, only the active regions 14 are illustrated.

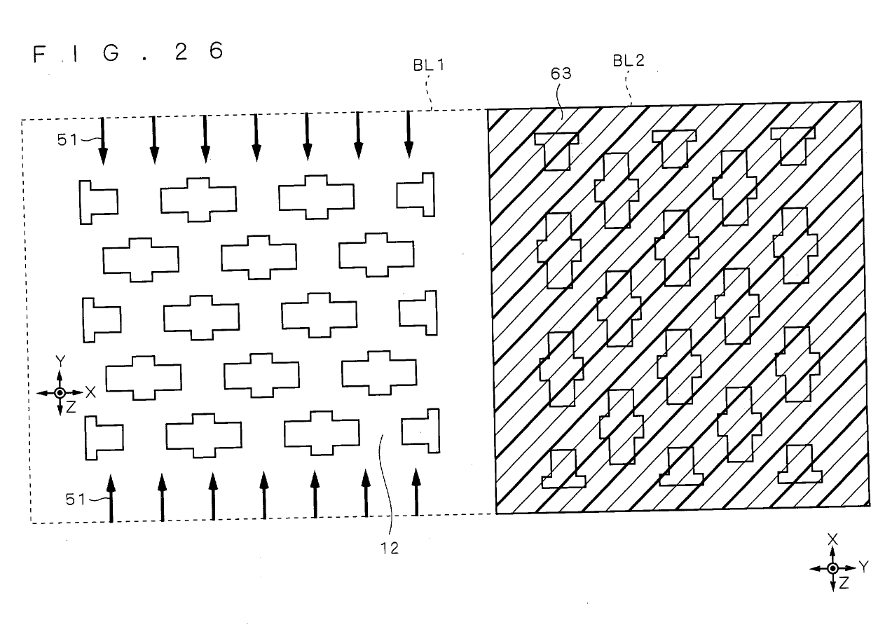

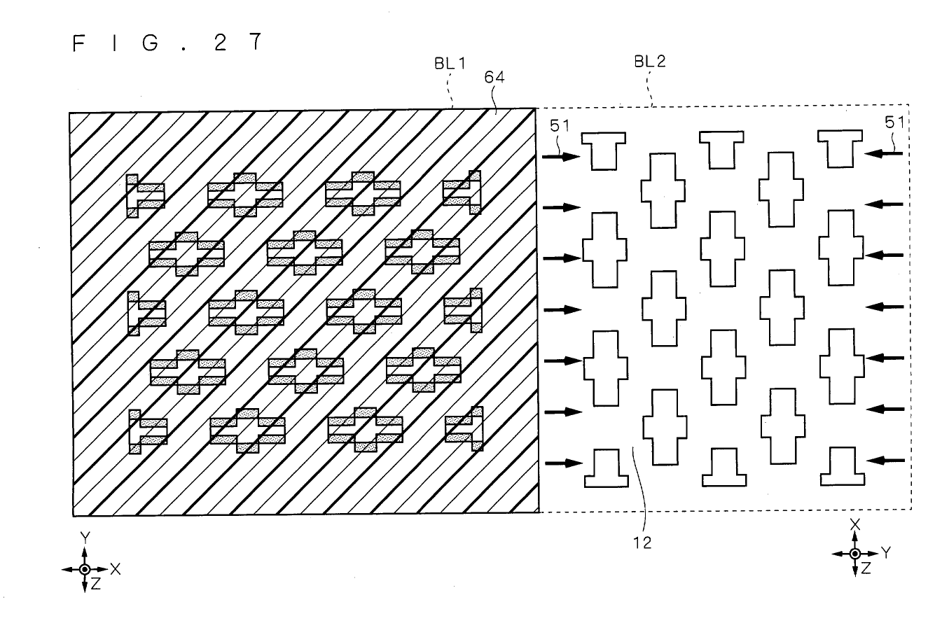

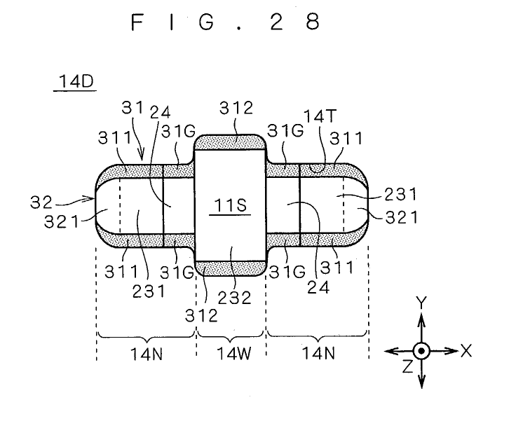

Next, referring to plane views of FIGS. 26 and 27, a manufacturing method of the semiconductor device 1E, especially, a manufacturing method of the high impurity concentration region 31 of the semiconductor device 1E is described. Besides, the description here centers on the difference of it from the manufacturing method of the semiconductor devices 1 and 1D.

In the same manner as the case of the semiconductor device 1D, the patterning mask 40 (refer to FIG. 6) is formed, the trench 12 is formed and the active regions 14 are formed in the respective blocks BL1 and BL2.

Moreover, the ion implantation of the impurities 51 to form the high impurity concentration region 31 is performed as described hereinafter. First, as shown in FIG. 26, the active regions 14 in the block BL2 are covered with a mask 63 such as the resist mask and so on, and the ion implantation of the impurities 51 is performed to the block BL1 in the same manner as the case of the semiconductor device 1 in a condition of having that mask 63. Next, as shown in FIG. 27, the active regions 14 in the block BL1 are covered with a mask 64 such as the resist mask an so on, and the ion implantation of the impurities 51 is performed to the block BL2 in the same manner as the case of the semiconductor device 1 in a condition of having that mask 64. Besides, the ion implantation to the block BL2 beforehand is also applicable.

At this time, in the same manner as the case of the semiconductor device 1, the ion implantation for the retrograde well 71 (refer to FIG. 1) and/or the ion implantation for the channel cut layer 72 (refer to FIG. 1) can also be performed being simultaneous with the ion implantation for the high impurity concentration region 31.

With regard to the other process, the manufacturing method of the semiconductor device 1, for example, is applicable.

Besides, the manufacturing method using the masks 63 and 64 described above is also applicable to a case that the blocks BL1 and BL2 have the active regions 14B or 14C, and moreover, it is also applicable to a case that types of the active regions are different between the blocks BL1 and BL2.

In the manufacturing method described above, the masks 63 and 64 are used, however, the size of the openings of those masks 63 and 64 is such as to expose the whole of the respective blocks BL1 and BL2, thus a design rule can be loose, differing from a case of the mask that only the part corresponding to the high impurity concentration region 31 described already is opened. According to this, a substantial increase of a cost does not occur.

Furthermore, it becomes easy to optimalize the implanting condition by using the masks 63 and 64. That is to say, in the manufacturing method of the preferred embodiment 4, without using the mask, it is necessary to select the implanting angle 0 to satisfy simultaneously both the condition tan⁻¹(dy/t)<θ<tan⁻¹ {(dy+py)/t} and the condition tan⁻¹(dx/t)<θ. In comparison with this, in the manufacturing method of the preferred embodiment 5, using the masks 63 and 64, the implanting angle θ only has to satisfy one condition θ<tan⁻¹(dy/t).

Besides, as described above, each of the blocks BL1 and BL2 includes the same structure with the memory cell region of the semiconductor device 1, thus according to the semiconductor device 1E, the same effect with the semiconductor device 1 can be obtained.

Modification example of the preferred embodiments 1 to 5.

For example, in the plane view of FIG. 3 and so on, a case that corner parts of the active region 14 are angular is illustrated, however, the corner parts described above can also be round such as an active region 14D shown in a plane view of FIG. 28. Besides, at this time, the side surface 14T of the active region 14D includes curved surfaces (which intersect both the X direction and the Y direction). Also with regard to the active regions 14B and 14C, the corner parts can be rounded.

In the case of the active region 14D having such a shape, if an implantation depth of the impurities 51 for the high impurity concentration region 31 is adjusted by controlling an accelerating energy, for example, it is possible to form the low impurity concentration region 32 on the border parts in the X direction in the active region 14 (in other words, in the parts intersecting the X direction in the side surface 14T of the active region 14D or the side surfaces intersecting the X direction).

Moreover, even if the active regions 14 and 14B do not have the wide width part 14W, that is to say, even if the sizes (the widths) in the Y direction are uniform, the high impurity concentration regions 31 and 31B can be formed.

Moreover, also in case that one MOSFET 20 is placed to the active regions 14 and 14B to 14D and in case that three or more MOSFETs 20 are placed to them, the high impurity concentration regions 31, 31B and 31C, the low impurity concentration regions 32, 32B and 32C and the source/drain regions 231 and 232 are applicable.

Moreover, if the capacitor 103 is connected with the source/drain region 232 in the wide width part 14W and the wirings 102 which serve as the bit lines are connected with the source/drain regions 231 in the narrow width parts 14N in the active regions 14 and 14B to 14D, the memory cell of what is called a dual port DRAM can be composed.

Moreover, the MOSFET 20 can also be a general MISFET (Metal-Insulator-Semiconductor Field Effect Transistor) or a general MIS type transistor.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
an active region including a main surface and a side surface;
a trench type element isolation positioned being in contact with said side surface;
a gate electrode extending, across said main surface, in a first direction which is parallel with said main surfaces;
a channel region which is placed in said main surface, facing with said gate electrode;
source/drain regions which are placed in said main surface, putting said channel region between;
a high impurity concentration region which is placed in said side surfaces which intersects said first direction, includes two gate electrode facing parts which face with said gate electrode and further face with each other in said first direction putting said channel region between, and has impurities of a similar conductivity type to said channel region at a higher concentration than that in a center part of said channel region; and
a low impurity concentration region which is placed in regions where said high impurity concentration region is not formed in said side surface, and a concentration of said impurities is lower than that of said high impurity concentration region.

2. The semiconductor device according to the claim 1, wherein
said low impurity concentration region includes a first part which is placed in a border part of said active region in a second direction running at right angles to said first direction and further being parallel with said main surface.

3. The semiconductor device according to claim 1, wherein
said low impurity concentration region includes plural second parts which are placed in border parts of said active region in said first direction, respectively.

4. The semiconductor device according to claim 1, further comprising
a capacitor which is connected with said source/drain region.
